(19) United States
(12) Patent Application Publication
(10) Pub. No.: US 2010/0033608 A1
(43) Pub. Date: Feb. 11, 2010

(54) Camera module and method of manufacturing the same

(75) Inventor: Go Min Chul, Suwon-si (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/289,334

(22) Filed: Oct. 24, 2008

(30) Foreign Application Priority Data
Aug. 6, 2008 (KR) 10-2008-0077150

(51) Int. Cl. H04N 5/335; H01L 21/00

(52) U.S. Cl. 348/294; 438/65; 257/E21.001; 348/E05.091

(57) ABSTRACT

Provided is a camera module including a housing that includes one or more lenses which are sequentially fixed and coupled and of which the focus does not need to be adjusted; an image sensor module that is coupled to a lower end portion of the housing; and a main substrate that is coupled to a lower end portion of the image sensor module through a reflow process. The image sensor module includes a module substrate including: a cylindrical upper cavity which is formed inside an upper end portion of the module substrate; a cylindrical lower cavity which is formed inside a lower end portion of the module substrate; and a filter mounting portion which is formed in such a manner that an IR filter seals the upper cavity; and a housing mounting portion which is formed in an upper end portion of the module substrate such that fine focus adjustment can be performed in a sliding manner when the image sensor module is coupled to the lower end portion of the housing; the IR filter which is mounted on the filter mounting portion formed in the module substrate; an image sensor which is fixed in the upper cavity, formed in the module substrate, through wire bonding; and a pad which is formed on a lower end portion of the module substrate and serves as a bonding medium during a reflow process.

### CROSS-REFERENCE TO RELATED APPLICATIONS

This application claims the benefit of Korean Patent Application No. 10-2008-0077150 filed with the Korean Intellectual Property Office on Aug. 6, 2008, the disclosure of which is incorporated herein by reference.

### BACKGROUND OF THE INVENTION

1. Field of the Invention

The present invention relates to a camera module and a method of manufacturing the same.

2. Description of the Related Art

Recently, camera modules are mounted on IT devices such as mobile terminals, PDAs (Personal Digital Assistant), MP3 players and so on. With the development of technology, the resolution of the camera modules changes from 300,000 pixels (VGA) to several million pixels, and the reduction in size and thickness of the camera modules are being performed depending on mounting targets. Further, the camera module provides various additional functions, such as auto-focusing (AF) and optical zoom.

The camera modules are manufactured by using main parts of charge coupled device (CCD) or complementary metal oxide semiconductor (CMOS) image sensors. Incident light transmitted through the lens is condensed by the image sensor and is stored as data in a memory. The stored data is displayed as an image through a display medium, such as liquid crystal display (LCD) or PC monitor.

Typical camera modules are manufactured by a chip-on-film (COF) method, a chip-on-board (COB) method and the like. The COB method will be described with reference to drawings.

FIG. 1 is an exploded perspective view of a conventional camera module manufactured by the COB method, and FIG. 2 is a cross-sectional view of the conventional camera module.

In the conventional camera module 10, a printed board 11 having a CCD or CMOS image sensor 12 mounted thereon through wire bonding is coupled to a lower end portion of a housing 13 formed of plastic, and a lens barrel 16 having a cylindrical body 14a extending downward is coupled to a lower end portion of a barrel 13a extending upward from the housing 13.

In the camera module 10, the housing 13 and the lens barrel 14 are coupled to each other by coupling a female screw portion 13b formed on the inner circumferential surface of the barrel 13a to a male screw portion 14b formed on the outer circumferential surface of the cylindrical body 14a.

Further, an IR filter 15 is interposed between a lens 14c mounted in the lens barrel 14 and the image sensor 12 attached on the upper surface of the printed board 11 so as to cut off excessive long-wavelength infrared rays incident on the image sensor 12.

In the camera module assembled in such a manner, while light incident from a specific object passes through the lens 14c, an image is inverted so that the focus is adjusted on the surface of the image sensor 12. At this time, when a focus is optimally adjusted while the lens barrel 14 screwed to the upper end of the housing 13 is rotated, an adhesive is injected between the barrel 13a of the housing 13 and the lens barrel 14 such that the housing 13 and the lens barrel 14 are bonded to each other. Then, the camera module is finalized.

In the camera module manufactured by the COB method, the lens barrel 14 is inserted into the upper opening of the housing 13 such that the lens barrel 14 and the housing 13 are closely coupled to each other through the screw coupling using the female and male screw portions 13b and 14b formed on the inner and outer circumferential surfaces of the housing 13 and the lens barrel 14. As height adjustment is performed by rotating the lens barrel 14 at the upper end portion of the housing 13, focus adjustment between the lens 14c within the lens barrel 14 and the image sensor 12 mounted on the printed board 11 is achieved.

Therefore, in the conventional camera modules manufactured by the above-described assembling method, when the housing 13 and the lens barrel 14 are vertically coupled, and if the female and male screws 13b and 14b are engaged at a distorted angle, screw threads may be broken or the coupling portion may be worn away by the friction between the female and male screws 13b and 14b. Then, foreign matters such as minute particles may occur, thereby degrading the assembling property.

Further, the particles occurring between the housing 13 and the lens barrel 14 inevitably fall onto the upper surface of the IR filter 14 or the light receiving region of the image sensor 12, because the housing 13 is rocked left and right when the focus adjustment is performed by rotating the lens barrel 14 mounted on the upper end portion of the housing 13. Therefore, when an image is reproduced by the image sensor 12, the particles have a large effect on the image.

Further, since the housing 13 and the lens barrel 14 are coupled though the male and female screws, the lens may be tilted along a spiral angle formed in the lens barrel 14 when the lens barrel 14 is rotated along the spiral contact surface.

Once foreign matters fall onto the lens 14c or the image sensor 12, they cannot be simply removed. Therefore, the camera module 10 in which the foreign matters have occurred should be discarded as a whole. As a result, the expensive lens 14c or the image sensor 12 is also discarded.

Further, since the housing 13 having the IR filter 15 coupled thereto is mounted on the printed board 11 after the image sensor 12 is wire-bonded to the printed board 11, movable foreign matters may fall into the housing 13, or specifically onto the upper end portion of the image sensor 12 such that defects frequently occur. Furthermore, since passive elements (not shown in FIG. 1) are mounted around the image sensor 12, flux or other foreign matters frequently occur.

Further, in order to quickly respond to users' request which changes day by day, a sample manufacturing schedule needs to be reduced by standardizing a camera module.

### SUMMARY OF THE INVENTION

An advantage of the present invention is that it provides a camera module which includes an image sensor module having an image sensor and an IR filter mounted therein, thereby minimizing foreign matters. Further, as the image sensor module is previously manufactured, it is possible to quickly respond to users' requests. Further, since a reflow process is adopted, it is possible to simplify the manufacturing process. Furthermore, when defects occur in the camera module, a rework operation can be easily performed, and the manufacturing cost can be reduced.

Another advantage of the invention is that it provides a method of manufacturing a camera module.

Additional aspect and advantages of the present general inventive concept will be set forth in part in the description which follows and, in part, will be obvious from the description, or may be learned by practice of the general inventive concept.

According to an aspect of the invention, a camera module comprises a housing that includes one or more lenses which are sequentially fixed and coupled and of which the focus does not need to be adjusted; an image sensor module that is coupled to a lower end portion of the housing; and a main substrate that is coupled to a lower end portion of the image sensor module through a reflow process. The image sensor module includes a module substrate including: a cylindrical upper cavity which is formed inside an upper end portion of the module substrate; a cylindrical lower cavity which is formed inside a lower end portion of the module substrate; and a filter mounting portion which is formed in such a manner that an IR filter seals the upper cavity; and a housing mounting portion which is formed in an upper end portion of the module substrate such that fine focus adjustment can be performed in a sliding manner when the image sensor module is coupled to the lower end portion of the housing; the IR filter which is mounted on the filter mounting portion formed in the module substrate; an image sensor which is fixed in the upper cavity, formed in the module substrate, through wire bonding; and a pad which is formed on a lower end portion of the module substrate and serves as a bonding medium during a reflow process.

The module substrate may be formed of a material on which the reflow process can be performed.

The material on which the reflow process can be performed may be a ceramic material.

The camera module further comprises passive elements that are mounted in the lower cavity formed in the module substrate.

The housing may include a support portion which extends from an inner lower end of the housing so as to come in contact with the upper end portion of the image sensor module. The support portion extends so as to be disposed on the upper end portion of the IR filter.

According to another aspect of the invention, there is provided a method of manufacturing a camera module, the camera module including a housing that includes one or more lenses which are sequentially fixed and coupled and of which the focus does not need to be adjusted; an image sensor module that is coupled to a lower end portion of the housing; and a main substrate that is coupled to a lower end portion of the image sensor module. The method comprises forming cylindrical upper and lower cavities inside upper and lower ends of a module substrate composing the image sensor module, respectively, and providing a bonding medium for a reflow process on a lower end of the module substrate; fixing an image sensor to the upper cavity of the module substrate through wire bonding; mounting an IR filter on the module substrate such that the IR filter seals the upper cavity, thereby completely manufacturing the image sensor module; bonding the image sensor module to the main substrate through a reflow process; and performing fine focus adjustment while sliding the housing into the housing mounting portion formed at the upper end portion of the module substrate coupled to the main substrate.

The method further comprises mounting passive elements in the lower cavity of the module substrate, before the fixing of the image sensor.

The housing may include a support portion which extends from an inner lower end of the housing so as to come in contact with the upper end portion of the image sensor module. The support portion extends so as to be disposed on the upper end portion of the IR filter.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is an exploded perspective view of a conventional camera module manufactured by the COB method;

FIG. 2 is a cross-sectional view of the conventional camera module;

FIG. 3 is a cross-sectional view of an image sensor module according to a first embodiment of the invention;

FIG. 4 is a cross-sectional view of a camera module according to a second embodiment of the invention;

FIG. 5 is a cross-sectional view of a camera module according to a third embodiment of the invention; and

FIGS. 6A to 6G are process diagrams sequentially showing a method of manufacturing a camera module according to the invention.

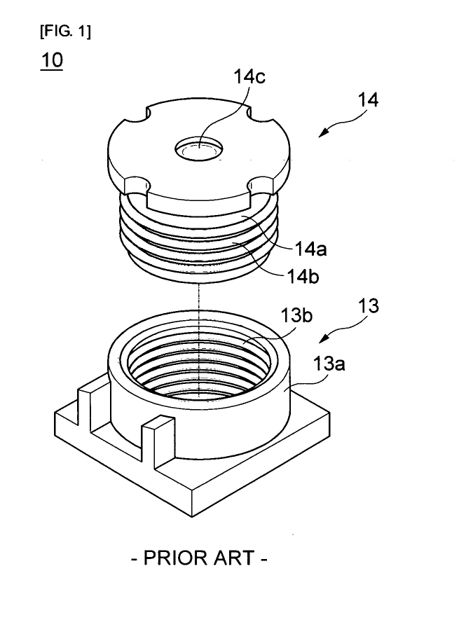

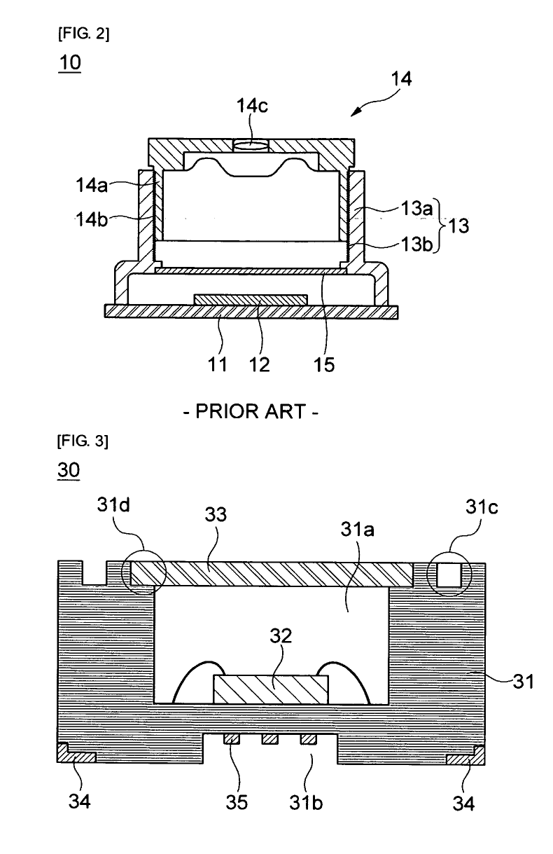

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to like elements throughout. The embodiments are described below in order to explain the present general inventive concept by referring to the figures.

Hereinafter, a camera module and a method of manufacturing the same according to embodiments of the present invention will be described in detail with reference to the accompanying drawings.

Camera Module

### First Embodiment

FIG. 3 is a cross-sectional view of an image sensor module 30 according to a first embodiment of the invention.

As shown in FIG. 3, the image sensor module 30 includes a module substrate 31, an image sensor 32, an IR filer 33, a pad 34, and passive elements 35.

The module substrate 30 has a cylindrical upper cavity 31a, a cylindrical lower cavity 31b, a housing mounting portion 31c, and a filter mounting portion 31d formed therein. For this construction, the module substrate 30 may be formed of a ceramic substrate. A general printed circuit board (PCB) has a disadvantage in that a groove is difficult to form. When the module substrate 30 is formed of a ceramic substrate, it can endure high-temperature heat during a reflow process.

The cylindrical upper cavity 31a is formed inside the upper end of the module substrate 31, and the cylindrical lower cavity 31b is formed inside the lower end of the module substrate 31.

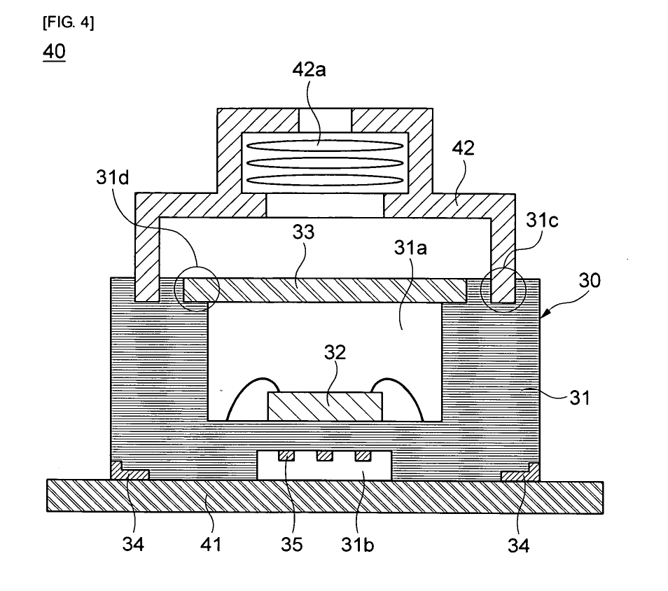

The housing mounting portion 31c is formed in the upper end portion of the module substrate 31 such that a housing 42 (refer to FIG. 4) can be mounted thereon. The filter mounting portion 31d having a stepped shape is formed at the boundary region between the upper end portion of the module substrate 31 and the upper cavity 31a such that the IR filter 33 can be mounted on the filter mounting portion 31d, the IR filter 33 sealing the upper cavity 31a. The depth of the filter mounting portion 31d corresponds to the thickness of the IR filter 33.

The pad 34 serving as a bonding medium for a reflow process is provided on a lower end portion of the module substrate 31. In general, a solder ball or pad is used as the bonding medium for a reflow process. Since the height of the solder ball increases the overall module height, the pad 34 is used as the bonding medium in this embodiment.

The image sensor 32 is mounted in the upper cavity 31a of the module substrate 31 and is fixed through wire bonding. The passive elements 35 such as an inductor, a capacitor, and a resistor are mounted in the lower cavity 31b. When the passive elements are mounted around the image sensor 32, foreign matters may have an effect upon the image sensor 32. Therefore, as the passive elements 35 are not mounted around the image sensor 32 but are disposed in the lower cavity 31b so as to be isolated from the image sensor 32, it is possible to minimize foreign matters, thereby protecting the image sensor 32.

The IR filter 33 is mounted on the filter mounting portion 31d. For example, the IR filter 33 is fixed to the module substrate 31 through an adhesive such as UV-bond. The IR filter 33 serves to cut off excessive infrared rays incident on the image sensor 32 and to ‘seal’ the upper cavity 31a of the image sensor module 30. In other words, the IR filter 32 serves as a cover glass for protecting the image sensor 32 within the image sensor module 30 from external contaminants which may occur during a variety of processes to be subsequently performed, even though it will be described below in a method of manufacturing a camera module.

In the related art, since the cover glass of the image sensor and the IR filter are doubly mounted, it has a bad effect upon an optical refractive index, thereby degrading an optical characteristic. In this embodiment, however, since the IR filter 33 serves as a cover glass, such a problem can be solved. Further, since the number of components used in the module can be reduced, the manufacturing cost and the overall size of the module can be reduced.

### Second Embodiment

FIG. 4 is a cross-sectional view of a camera module 40 according to a second embodiment of the invention.

In this embodiment, the descriptions of the same technical construction as that of the first embodiment will be omitted, and like reference numerals will be attached to the same components.

The camera module 40 according to the second embodiment includes a main substrate 41, a housing 42, and the above-described image sensor module 30.

First, the image sensor module 30 according to the first embodiment is mounted on the main substrate 41, and a reflow process is then performed.

In the conventional COB method, the process for bonding a camera module to a main substrate was separately performed. However, in the reflow process according to the invention, a plurality of image sensor modules 30 can be bonded to a plurality of main substrates 41 through one process, because the pad 34 is provided between the image sensor module 30 and the main substrate 41. Therefore, it is possible to simplify the manufacturing process.

However, since a general reflow process is performed at a high temperature of about 250° C., it was difficult to apply the reflow process to a camera module which is manufactured by the COB method and uses a housing formed of plastic such as PVC.

However, since the module substrate 31 of the image sensor module 30 is formed of a ceramic substrate on which the reflow process can be performed, only the previously-manufactured image sensor module 30 can be attached to the main substrate 41 through the reflow process, before the housing 42 including lenses 42a is installed.

According to this embodiment, a standardized and commonly-used module can be previously manufactured as the image sensor module 30 so as to be mounted on the main substrate 40 depending on a users request, which makes it possible to quickly respond to the user's request. Therefore, it is possible to reduce the manufacturing time.

Further, in the conventional camera module, individual components were sequentially assembled. In this embodiment, however, since the image sensor module 30 is manufactured in advance, the manufacturing process can be simplified. Further, a rework operation can be easily performed when defects occur in the camera module, and the lenses or image sensor can be reused.

Meanwhile, after the image sensor module 30 is bonded to the main substrate 41, the housing 42 is mounted on the upper end portion of the image sensor module 30. The housing 42 includes one or more lenses 42a which are sequentially fixed and coupled and of which the focus does not need to be adjusted. In this case, the housing 42 is inserted into the housing mounting portion 31c of the module substrate 31, while being vertically adjusted in a sliding manner. Therefore, the depth of the housing mounting portion 31c is designed in such a manner that a focal distance (i.e., a distance from the lower end of the lens to the upper end of the image sensor) can be adjusted.

In the conventional camera module manufactured by the COB method, since the lens barrel and the housing are coupled through the male and female screw portions, the screw adjustment should be performed so as to adjust a focal distance. Accordingly, foreign matters may occur during the screw adjustment. In this embodiment, however, since the housing 42 is adjusted in a sliding manner, it is possible to minimize foreign matters.

### Third Embodiment

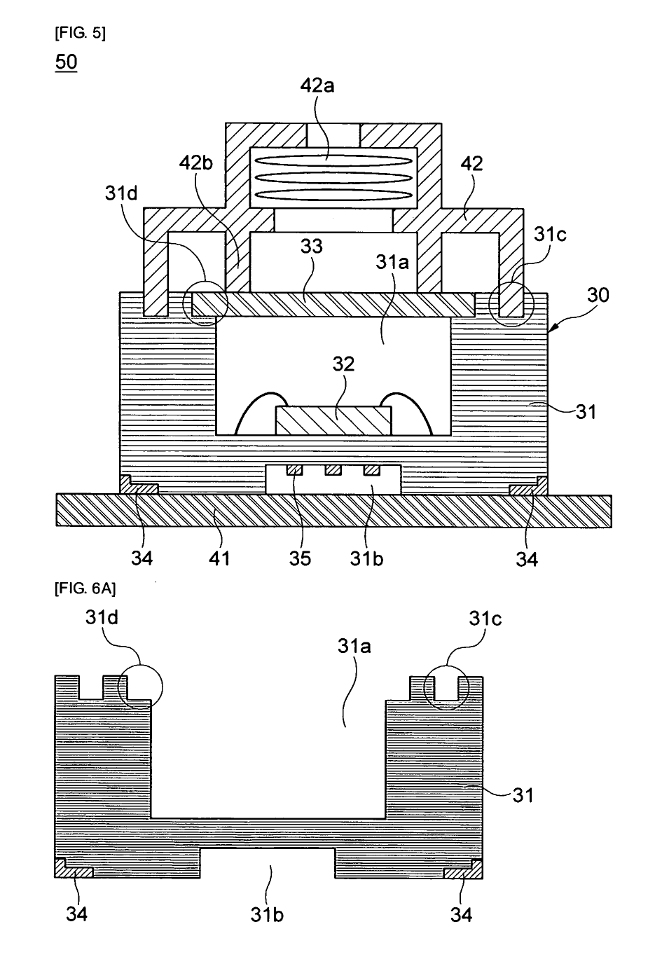

FIG. 5 is a cross-sectional view of a camera module 50 according to a third embodiment of the invention.

In this embodiment, the descriptions of the same technical construction as those of the first and second embodiments will be omitted, and like reference numerals will be attached to the same components.

The housing 42 further includes a support portion 42b which extends from an inner lower end of the housing 42 so as to come in contact with the upper end portion of the image sensor module. That is, the housing 42 further includes the cylindrical support portion 42b formed at the inner lower end thereof. The support portion 42b may be disposed on the upper end portion of the IR filter 33.

As the support portion 42b is adopted, the housing 42 and the image sensor module 30 can be coupled more reliably. Further, when the housing 42 is coupled, the housing 42 can be inserted into the module substrate 31 without a separate height adjustment process. In other words, the height of the support portion 42b is determined after a desirable focal distance is previously calculated. Then, the housing 42 can be inserted into the module substrate 42 without a separate height adjustment process. Therefore, it is possible to prevent an image error caused by ‘tilting’ when the image sensor module and the housing are coupled.

Method of Manufacturing Camera Module

Hereinafter, a method of manufacturing a camera module according to an embodiment of the invention will be described.

In this embodiment, the descriptions of the same technical construction as those of the first to third embodiments will be omitted, and like reference numerals will be attached to the same components.

First, an image sensor module 30 is manufactured, and a main substrate 41 and the image sensor module 30 are bonded to each other through a reflow process. Then, a housing 42 is mounted on the upper end portion of the image sensor module 30. Since a general reflow process is performed at a high temperature of about 250° C., the housing 42 formed of plastics such as PVC is mounted on the image sensor module 30 after the reflow process.

The image sensor module 30 is manufactured through the following process.

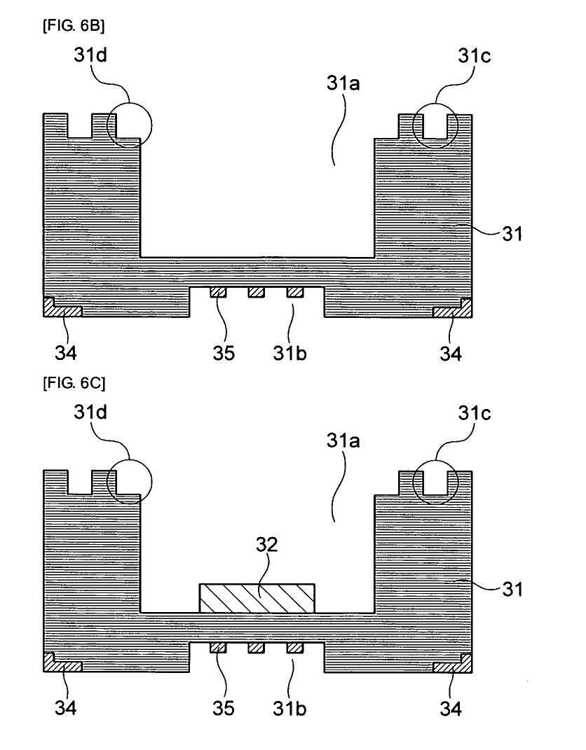

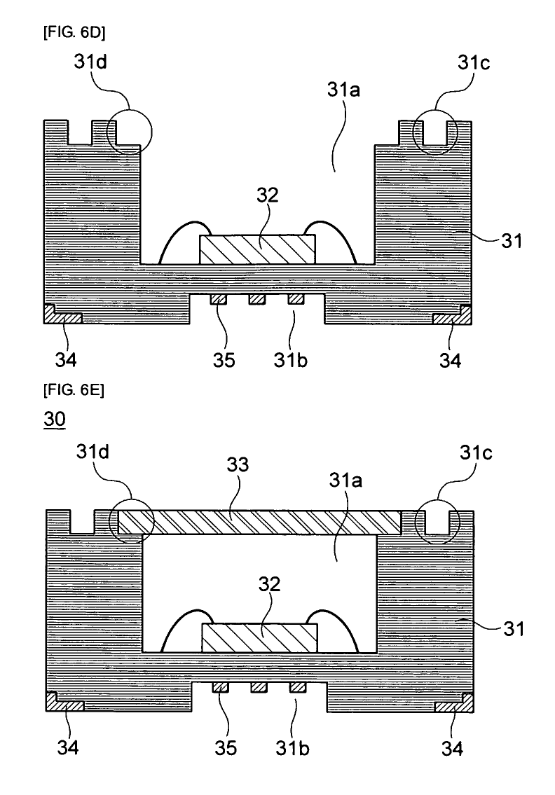

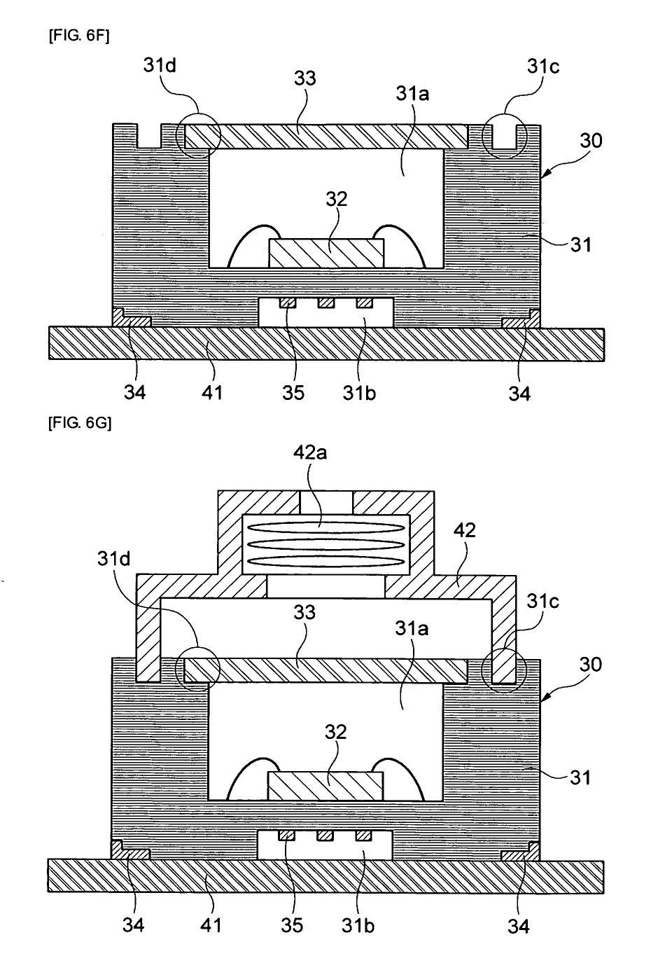

First, a cylindrical upper cavity 31a, a cylindrical lower cavity 31b, a housing mounting portion 31c, and a filter mounting portion 31d are formed in a module substrate 31 composing the basic structure of the image sensor module 30 (refer to FIG. 6A). For this construction, the module substrate 31 may be formed of a ceramic substrate. A general PCB has a disadvantage in that a groove is difficult to form. When a ceramic substrate is used, it can endure high-temperature heat generated during a reflow process.

The cylindrical upper cavity 31a is formed inside the upper end of the module substrate 31, and the cylindrical lower cavity 31b is formed inside the lower end of the module substrate 31.

The housing mounting portion 31c is formed in the upper end portion of the module substrate 31 such that a housing 42 can be mounted thereon. The filter mounting portion 31d having a stepped shape is formed at the boundary region between the upper end of the module substrate 31 and the upper cavity 31a such that the IR filter 33 can be mounted thereon, the IR filter 33 sealing the upper cavity 31a. The depth of the filter mounting portion 31d corresponds to the thickness of the IR filter 33.

A pad 34 serving as a bonding medium for a reflow process is provided on a lower end of the module substrate 31 (refer to FIG. 6B). Passive elements 35 such as an inductor, a capacitor, and a resistor are mounted in the lower cavity 31b (refer to FIG. 6C). The image sensor 32 is mounted in the upper cavity 31a of the module substrate 31 and is fixed through wire bonding (refer to FIG. 6D). When the passive elements are mounted around the image sensor 32, foreign matters may have an effect upon the image sensor 32. Therefore, as the passive elements 35 are not mounted around the image sensor 32 but are disposed in the lower cavity 31b so as to be isolated from the image sensor 32, it is possible to minimize foreign matters, thereby protecting the image sensor 32.

The IR filter 33 is mounted on the filter mounting portion 31c (refer to FIG. 6E). In this case, an adhesive such as UV bond may be used. As the upper end of the upper cavity 31a is sealed by the IR filter 33, the IR filter 32 may serve as a cover glass for protecting the expensive image sensor 32 within the image sensor module 30 from foreign matters which may occur during a variety of processes to be subsequently performed.

Then, the image sensor module 30 manufactured in such a manner is bonded to the main substrate 41 through a reflow process (refer to FIG. 6F). In this case, since a plurality of image sensor modules can be bonded to a plurality of main substrates, respectively, a large quantity of modules can be bonded through one process, thereby contributing to simplifying the manufacturing process. Further, since the image sensor module 30 is manufactured in advance, it is possible to quickly respond to users' requests, thereby reducing the manufacturing time. That is because, since proper main substrates 41 are bonded through the reflow process in accordance with users' requests, mass production can be achieved.

After the image sensor module 30 and the main substrate 41 are bonded, the housing 42 is mounted on the housing mounting portion 31c of the image sensor module 30 in a sliding manner (refer to FIG. 6G). While the housing 42 is slowly slid into the housing mounting portion 31c of the image sensor module 30, fine focus adjustment is performed. Therefore, it is possible to minimize foreign matters caused by the screw adjustment in the conventional screw coupling method.

According to the present invention, as the image sensor module is manufactured in advance, the module can be commonly-used and standardized, which makes it possible to quickly respond to users' requests. As the housing 42 is inserted in a sliding manner, it is possible to minimize foreign matters. Further, as the reflow process is adopted, the manufacturing process can be simplified, thereby contributing to enhancing throughput. Further, when defects occur in the camera module, a rework operation can be easily performed, and the image sensor can be reused, which makes it possible to reduce the manufacturing cost. Therefore, it is possible to enhance the reliability of the camera module and to achieve the standardization.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A camera module comprising:
a housing that includes one or more lenses which are sequentially fixed and coupled and of which the focus does not need to be adjusted;
an image sensor module that is coupled to a lower end portion of the housing; and
a main substrate that is coupled to a lower end portion of the image sensor module through a reflow process,
wherein the image sensor module includes:
a module substrate including:
a cylindrical upper cavity which is formed inside an upper end portion of the module substrate;
a cylindrical lower cavity which is formed inside a lower end portion of the module substrate; and
a filter mounting portion which is formed in such a manner that an IR filter seals the upper cavity; and
a housing mounting portion which is formed in an upper end portion of the module substrate such that fine focus adjustment can be performed in a sliding manner when the image sensor module is coupled to the lower end portion of the housing;
the IR filter which is mounted on the filter mounting portion formed in the module substrate;
an image sensor which is fixed in the upper cavity, formed in the module substrate, through wire bonding; and
a pad which is formed on a lower end portion of the module substrate and serves as a bonding medium during a reflow process.

2. The camera module according to claim 1, wherein the module substrate is formed of a material on which the reflow process can be performed.

3. The camera module according to claim 2, wherein the material on which the reflow process can be performed is a ceramic material.

4. The camera module according to claim 1 further comprising:
passive elements that are mounted in the lower cavity formed in the module substrate.

5. The camera module according to claim 1, wherein the housing includes a support portion which extends from an inner lower end of the housing so as to come in contact with the upper end portion of the image sensor module.

6. The camera module according to claim 5, wherein the support portion extends so as to be disposed on the upper end portion of the IR filter.

7. A method of manufacturing a camera module, the camera module including a housing that includes one or more lenses which are sequentially fixed and coupled and of which the focus does not need to be adjusted; an image sensor module that is coupled to a lower end portion of the housing; and a main substrate that is coupled to a lower end portion of the image sensor module, the method comprising:
forming cylindrical upper and lower cavities inside upper and lower ends of a module substrate composing the image sensor module, respectively, and providing a bonding medium for a reflow process on a lower end of the module substrate;
fixing an image sensor to the upper cavity of the module substrate through wire bonding;
mounting an IR filter on the module substrate such that the IR filter seals the upper cavity, thereby completely manufacturing the image sensor module;
bonding the image sensor module to the main substrate through a reflow process; and
performing fine focus adjustment while sliding the housing into the housing mounting portion formed at the upper end portion of the module substrate coupled to the main substrate.

8. The method according to claim 7 further comprising:
mounting passive elements in the lower cavity of the module substrate, before the fixing of the image sensor.

9. The method according to claim 7, wherein the housing includes a support portion which extends from an inner lower end of the housing so as to come in contact with the upper end portion of the image sensor module.

10. The method according to claim 9, wherein the support portion extends so as to be disposed on the upper end portion of the IR filter.
